(19) United States
(12) Patent Application Publication
(10) Pub. No.: US 2025/0169320 A1
(43) Pub. Date: May 22, 2025

(54) Display Device

(71) Applicant: LG Display Co., Ltd., Seoul (KR)

(72) Inventors: Hoonsok Son, Paju-si (KR); Goeun Lim, Paju-si (KR)

(21) Appl. No.: 18/760,959

(22) Filed: Jul. 1, 2024

(30) Foreign Application Priority Data
Nov. 21, 2023 (KR) 10-2023-0162101

(51) Int. Cl. H10K 59/38; H01L 25/075; H01L 33/50; H01L 33/60; H10K 59/121; H10K 59/122; H10K 59/80

(52) U.S. Cl. CPC H10K 59/38; H01L 25/0753; H10H 20/851; H10H 20/856; H10K 59/1213; H10K 59/122; H10K 59/878

(57) ABSTRACT

A display device includes a substrate having a pixel including a plurality of sub-pixels, an insulating layer on the substrate and including an indentation at boundaries between the plurality of sub-pixels, an organic light emitting diode including a common emission layer on the insulating layer, and a color filter layer on the organic light emitting diode, wherein the color filter layer includes color filters and a reflective member between adjacent color filters.

### CROSS REFERENCE TO RELATED APPLICATION

The present application claims priority to Republic of Korea Patent Application No. 10-2023-0162101, filed Nov. 21, 2023, which is incorporated hereby incorporated by reference in its entirety.

### BACKGROUND

### Field of Technology

The present specification relates to a display device.

### Description of the Related Art

As the information society develops, various demands for display devices for displaying images are increasing, and various types of display devices such as liquid crystal display (LCD) devices and organic light emitting diode (OLED) display devices are utilized.

Among the display devices, there is an advantage in that the OLED display devices as the self-luminous types have superior viewing angles and contrast ratios than the LCD devices, and are lighter and thinner and have low power consumption because they do not require a separate backlight. In addition, there is an advantage in that the OLED display devices may drive at a low DC voltage, have a fast response time, and especially low manufacturing costs.

Recently, demand for displays requiring augmented reality (AR), virtual reality (VR) or equivalent ultra-high resolution using an OLED display device is increasing.

Meanwhile, the OLED display device may include a red sub-pixel, a green sub-pixel, and a blue sub-pixel, and research for reducing light color mixing between adjacent sub-pixels is being conducted.

### SUMMARY

The present specification is directed to providing a display device which can prevent or at least reduce light color mixing between adjacent sub-pixels.

The present specification is also directed to providing a display device which can minimize or at least reduce light loss by reflecting light escaped to a lower portion of an organic light emitting diode (OLED).

The objects of the present specification are not limited to the above-described object, and other technical objects may be inferred from embodiments below.

In one embodiment, a display device comprises: a substrate having a pixel including a plurality of sub-pixels; an insulating layer on the substrate, the insulating layer including an indentation that extends in a direction towards a lower surface of the substrate and the indentation located at boundaries between the plurality of sub-pixels; an organic light emitting diode including a common emission layer on the insulating layer, the common emission layer in each of the plurality of sub-pixels; and a color filter layer on the organic light emitting diode, the color filter layer including a plurality of color filters and a reflective member between adjacent color filters from the plurality of color filters.

In one embodiment, a display device comprises: a substrate having a pixel including a plurality of sub-pixels; an insulating layer on the substrate, the insulating layer including an indentation that extends in a direction towards a lower surface of the substrate and the indentation located at boundaries between the plurality of sub-pixels; a plurality of transistors in the insulating layer, each of the plurality of transistors included in a corresponding one of the plurality of sub-pixels; and a plurality of organic light emitting diodes that are each included in a corresponding one of the plurality of sub-pixels, each organic light emitting diode including a first electrode on the insulating layer and electrically connected to a corresponding transistor from the plurality of transistors, a common emission layer on the first electrode and is common to the plurality of organic light emitting diodes, and a second electrode on the common emission layer and is common to the plurality of organic light emitting diodes, wherein the first electrode of at least one of the plurality of organic light emitting diodes includes a transparent layer on the insulating layer and a reflective layer that electrically connects the corresponding transistor with the transparent layer, and the reflective layer includes an inclined surface with respect to an extension direction of the substrate.

In one embodiment, a display device comprises: a substrate having a pixel including a plurality of sub-pixels; an insulating layer on the substrate, the insulating layer including an indentation that extends in a direction towards a lower surface of the substrate and the indentation located at boundaries between the plurality of sub-pixels; an organic light emitting diode including a common emission layer on the insulating layer, the common emission layer in each of the plurality of sub-pixels; and a color filter layer on the organic light emitting diode, the color filter layer including a plurality of color filters and a portion of each of the plurality of color filters is in the indentation.

In one embodiment, a display device comprises: a substrate including a plurality of sub-pixels; an insulating layer on the substrate; a plurality of light emitting diodes, each of the plurality of light emitting diodes included in a corresponding one of the plurality of sub-pixels and comprises a first electrode on an upper surface of the insulating layer, an emission layer on the first electrode and included in the plurality of sub-pixels, and a second electrode on the first electrode and included in the plurality of sub-pixels; and a plurality of color filters over the plurality of light emitting diodes, wherein a portion of a color filter from the plurality of color filters that is located at a boundary between adjacent sub-pixels from the plurality of sub-pixels is closer to the substrate than a lower surface of the first electrode.

According to the embodiments, by arranging the reflective member at the boundary between the adjacent sub-pixels, it is possible to improve light color mixing between the adjacent sub-pixels. In addition, since the reflective member reflects the light emitting from each of the sub-pixels, it is possible to minimize or at least reduce light loss. In addition, since the color filter of each of the sub-pixels and the reflective member positioned at the boundary between the adjacent sub-pixels may be disposed to extend downward from the transparent layer, it is possible to further minimize or at least reduce light loss.

In addition, by forming the reflective layer of the display device to be inclined with respect to the extension direction of the substrate, the light reflected by the reflective member disposed at the boundary between the adjacent sub-pixels may be reflected upward. Therefore, it is possible to minimize or at least reduce the light loss due to the light escaped downward from the organic light emitting diode (OLED).

In addition, the color filter of another color may be additionally disposed at the boundary between the adjacent color filters. Therefore, it is possible to improve light leakage and improve light color mixing between the adjacent sub-pixels.

However, the effects obtainable from the present specification are not limited to the above-described effects, and other effects that are not mentioned will be able to be clearly understood by those skilled in the art to which the present specification pertains from the following description.

Detailed matters of other embodiments are included in a detailed description and accompanying drawings.

### BRIEF DESCRIPTION OF THE DRAWINGS

FIG. 1 is a plan view of a display device according to one embodiment.

FIG. 2 is a cross-sectional view of the display device along line A-A′ in FIG. 1 according to one embodiment.

FIG. 3 is a cross-sectional view of an organic light emitting diode (OLED) according to FIG. 2 according to one embodiment.

FIG. 4 is a cross-sectional view of an OLED according to a modified example of FIG. 2 according to one embodiment.

FIG. 5 is an enlarged view of area Q1 in FIG. 2 according to one embodiment.

FIG. 6 is a modified example of the OLED of FIG. 5 according to one embodiment.

FIGS. 7 to 12 are cross-sectional views for each process showing a method of manufacturing the display device according to one embodiment.

FIG. 13 is a cross-sectional view of a display device according to another embodiment.

FIG. 14 is an enlarged view of area Q2 in FIG. 13 according to one embodiment.

FIG. 15 is a modified example of the display device of FIG. 14 according to one embodiment.

FIGS. 16 to 19 are cross-sectional views for each process showing a method of manufacturing the display device according to another embodiment.

FIG. 20 is a cross-sectional view of a display device according to still another embodiment.

FIG. 21 is a cross-sectional view of a display device according to still another embodiment.

FIG. 22 is an enlarged view of area Q3 in FIG. 21 according to one embodiment.

FIGS. 23 to 26 are cross-sectional views for each process showing a method of manufacturing the display device according to still another embodiment.

FIG. 27 is a cross-sectional view of a display device according to yet another embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

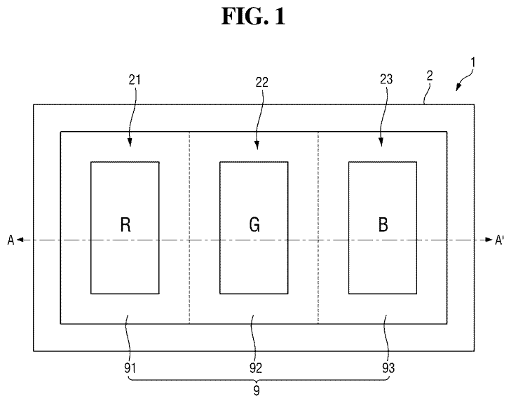

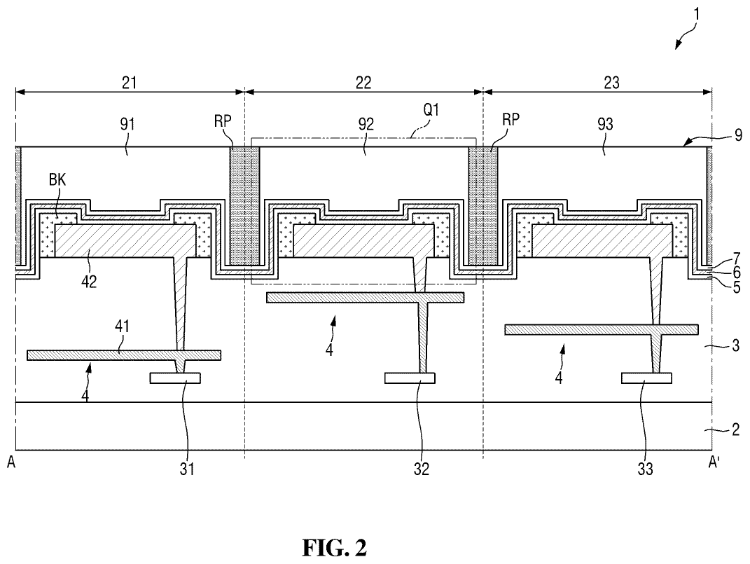

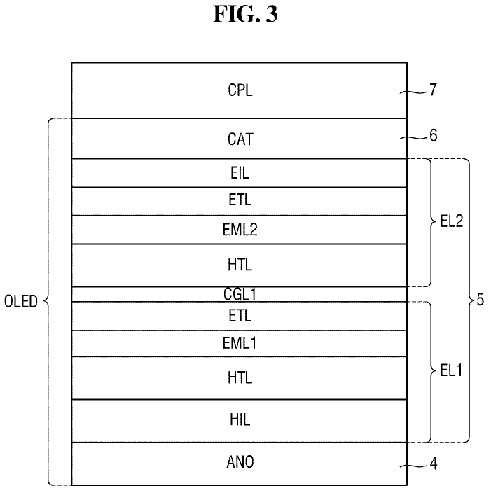

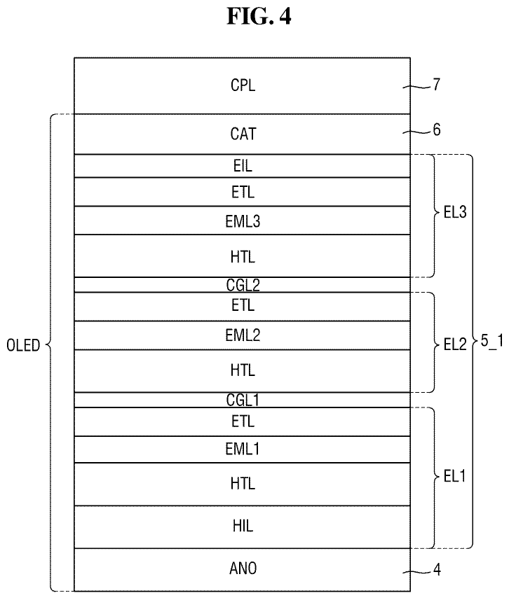

FIG. 1 is a plan view of a display device according to one embodiment. FIG. 2 is a cross-sectional view of the display device along line A-A′ in FIG. 1 according to one embodiment. FIG. 3 is a cross-sectional view of an organic light emitting diode (OLED) according to FIG. 2 according to one embodiment. FIG. 4 is a cross-sectional view of an OLED according to a modified example of FIG. 2 according to one embodiment.

Referring to FIGS. 1 to 4, a display device 1 according to one embodiment includes a substrate 2, a first electrode 4, a bank BK, a common emission layer 5, and a second electrode 6.

A plurality of sub-pixels 21, 22, and 23 are formed on the substrate 2. The plurality of sub-pixels 21, 22, and 23 may form one pixel. The plurality of pixels may be formed on the substrate 2.

The plurality of sub-pixels 21, 22, and 23 include a first sub-pixel 21, a second sub-pixel 22, and a third sub-pixel 23. Since the first sub-pixel 21, the second sub-pixel 22, and the third sub-pixel 23 may be disposed sequentially, the second sub-pixel 22 may be disposed adjacent to one side, for example, the left side of the first sub-pixel 21, and the third sub-pixel 23 may be disposed adjacent to one side, for example, the left side of the second sub-pixel 22.

Throughout the present specification, when two sub-pixels are disposed adjacent to each other, it should be construed to mean that no other sub-pixels are disposed between the two sub-pixels.

Although the first sub-pixel 21 may be provided to emit red (R) light, the second sub-pixel 22 may be provided to emit blue (B) light, and the third sub-pixel 23 may be provided to emit green (G) light, the present disclosure is not necessarily limited thereto.

Although FIG. 1 shows that the pixel includes only three sub-pixels 21, 22, and 23, the present specification is not limited thereto, and the pixel may include four sub-pixels. When the pixel includes four sub-pixels, the pixel may further include a fourth sub-pixel provided to emit white (W) light.

Each of the first to third sub-pixels 21, 22, and 23 may have the same size. For example, each of the first to third sub-pixels 21, 22, and 23 may have the same width and the same height. Here, although the width may indicate a horizontal direction based on FIG. 1, and the height may indicate a direction perpendicular to the width based on FIG. 1, the present invention is not necessarily limited thereto.

The bank BK may be disposed between the first sub-pixel 21, the second sub-pixel 22, and the third sub-pixel 23. The bank BK according to one embodiment is used to distinguish the first sub-pixel 21, the second sub-pixel 22, and the third sub-pixel 23.

The first electrode 4 is patterned for each of the sub-pixels 21, 22, and 23. In other words, one first electrode 4 is formed in the first sub-pixel 21, another first electrode 4 is formed in the second sub-pixel 22, and the remaining first electrode 4 is formed in the third sub-pixel 23. The first electrode 4 may function as an anode of the display device 1. The bank BK may be provided to cover an edge of the first electrode 4 disposed in each of the first to third sub-pixels 21, 22, and 23 to distinguish the first sub-pixel 21, the second sub-pixel 22, and the third sub-pixel 23. Therefore, an emission area can be defined by the bank BK.

In the display device 1, the first electrode 4 may be provided as a plurality of layers including a reflective layer 41, thereby further increasing light extraction efficiency using the micro cavity characteristic.

The micro cavity characteristic indicates a characteristic that when a distance between the reflective layer 41 and the second electrode 6 is an integer multiple of a half wavelength (λ/2) of light emitted from the sub-pixel, constructive interference occurs to amplify the light, and when a reflection and re-reflection process is repeated between the reflective layer 41 and the second electrode 6, the degree of amplified light continuously increases, thereby increasing the external extraction efficiency of light.

The common emission layer 5 may emit white light. For example, the common emission layer 5 may emit white light by being provided in a two-stack structure including a blue emission layer, a yellow-green emission layer, and a charge generation layer or is provided in a three-stack structure including the blue emission layer, a green emission layer, a red emission layer, and the charge generation layer, but is not necessarily limited thereto, and may be provided in a plurality of layers exceeding 3 stacks as long as it may emit white light.

The common emission layer 5 may be formed as a common layer throughout all of the first to third sub-pixels 21, 22, and 23. Therefore, the common emission layer 5 may cover the first electrode 4 disposed in each sub-pixel and the bank BK disposed between the sub-pixels.

The second electrode 6 is used to form an electric field with the first electrode 4 and may function as a cathode. The second electrode 6 may be disposed on an upper surface of the common emission layer 5, which is opposite to a lower surface of the common emission layer 5 with which the first electrode 4 is in contact, and provided as a common layer throughout the first to third sub-pixels 21, 22, and 23.

In the case of the top emission type, the second electrode 6 may be provided as a transparent electrode, and in the case of the bottom emission type, the second electrode 6 may be provided as an opaque electrode including a reflective material. In the case of the top emission type, the second electrode 6 may be formed as a translucent electrode to increase light extraction efficiency using the micro cavity characteristic. Since the display device increases light extraction efficiency using the micro cavity characteristic in the top emission type, an example in which the second electrode 6 is formed as the translucent electrode will be described.

A color filter layer 9 is provided in each of the first to third sub-pixels 21, 22, and 23 to block a specific color from light emitted from the emission layer of each sub-pixel.

A first color filter 91 provided in the first sub-pixel 21 may be provided to block light of other colors excluding red (R) light. Thus, the first color filter 91 allows transmission of red light. In this case, the first color filter 91 may be provided as a red color filter. A second color filter 92 provided in the second sub-pixel 22 may be provided to block light of other colors excluding blue (B) light. Thus, the second color filter 92 allows transmission of blue light. In this case, the second color filter 92 may be provided as a blue color filter. A third color filter 93 provided in the third sub-pixel 23 may be provided to block light of other colors excluding green (G) light. Thus, the third color filter 93 allows transmission of green light. In this case, the third color filter 93 may be provided as a green color filter. However, the present specification is not necessarily limited thereto.

The first to third color filters 91, 92, and 93 provided in the first to third sub-pixels 21, 22, and 23, respectively may be provided in the same size as each sub-pixel or provided by being reduced or enlarged at a constant ratio with respect to each sub-pixel.

Hereinafter, the stacked structure of the display device 10 according to one embodiment will be described in detail.

The display device 1 according to one embodiment includes the substrate 2, the insulating layer 3, the first electrode 4, the bank BK, the common emission layer 5, the second electrode 6, a capping layer 7, and the color filter layer 9.

The substrate 2 may be a plastic film, a glass substrate, or a semiconductor substrate such as silicon.

The substrate 2 may be made of a transparent material or an opaque material. The first sub-pixel 21, the second sub-pixel 22, and the third sub-pixel 23 are provided on the substrate 2. The first sub-pixel 21 may be provided to emit red (R) light, the second sub-pixel 22 may be provided to emit blue (B) light, and the third sub-pixel 23 may be provided to emit green (G) light.

The display device 1 according to one embodiment is configured in a so-called top emission type in which the emitted light is emitted upward, and thus a material of the substrate 100 may include not only a transparent material but also an opaque material. The color filters 91, 92, and 93 may be respectively provided above the first to third sub-pixels 21, 22, and 23 from which light is emitted to transmit light of the same color.

The insulating layer 3 is formed on the substrate 2. The insulating layer 3 may be provided as a plurality of stacked insulating layers, but in FIG. 2, for convenience of description, it is shown that the insulating layer 3 is provided as one layer. The insulating layer 3 is provided with circuit elements including a plurality of thin film transistors 31, 32, and 33, various signal lines, capacitors, and the like for each sub-pixel 21, 22, and 23. The signal lines may include a gate line, a data line, a power line, and a reference line, and the thin film transistors 31, 32, and 33 may include a switching thin film transistor, a driving thin film transistor, and a sensing thin film transistor. Each of the sub-pixels 21, 22, and 23 is defined by an intersection structure of gate lines and data lines.

The switching thin film transistor functions to supply the data voltage supplied from the data line to the driving thin film transistor by being switched according to a gate signal supplied to the gate line.

The driving thin film transistor functions to generate and supply a data current from the power supplied from the power line to the first electrode 4 by being switched according to the data voltage supplied from the switching thin film transistor.

The sensing thin film transistor functions to sense a threshold voltage deviation of the driving thin film transistor, which causes the degradation of image quality, and supplies the current of the driving thin film transistor to the reference line in response to a sensing control signal supplied from the gate line or a separate sensing line.

The capacitor functions to maintain the data voltage supplied to the driving thin film transistor for one frame and is connected to each of a gate terminal and a source terminal of the driving thin film transistor.

The first transistor 31, the second transistor 32, and the third transistor 33 are disposed for each individual sub-pixel 21, 22, and 23 in the first insulating layer 3a. The first transistor 31 according to one embodiment may be connected to the first electrode 4 disposed on the first sub-pixel 21 to apply a driving voltage for emitting light of a color corresponding to the first sub-pixel 21.

The second transistor 32 according to one embodiment may be connected to the first electrode 4 disposed on the second sub-pixel 22 to apply a driving voltage for emitting light of a color corresponding to the second sub-pixel 22.

The third transistor 33 according to one embodiment may be connected to the first electrode 4 disposed on the third sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 according to one embodiment supplies a predetermined current to the emission layer according to the data voltage of the data line. Therefore, the emission layer of each of the first sub-pixel 21, the second sub-pixel 22, and the third sub-pixel 23 may emit light with a predetermined brightness according to the predetermined current.

The first electrode 4 of the first sub-pixel 21 or the reflective layer to be described below may be disposed inside or above the insulating layer 3.

The first electrode 4 is patterned for each of the first to third sub-pixels 21, 22, and 23. The first electrode 4 is connected to the driving thin film transistor provided in the insulating layer 3. Specifically, the first electrode 4 is connected to the source terminal or the drain terminal of the driving thin film transistor. To this end, a contact hole for exposing the source terminal or the drain terminal of the driving thin film transistor is formed in the insulating layer 3, and the first electrode 4 is connected to the source terminal or the drain terminal of the driving thin film transistor through the contact hole.

The display device 1 according to one embodiment may be provided in the top emission type, and to this end, the first electrode 4 may be provided to reflect light emitted from the common emission layer 5 upward. In this case, the first electrode 4 has a double layer structure including the reflective layer 41 (or a reflective electrode or a reflector) for reflecting light, and a transparent layer 42 (or a transparent electrode, an ITO electrode, or an anode) for supplying holes to the common emission layer 5.

The reflective layer 41 may reflect the light emitted toward the reflective layer 41 among the light emitted from the common emission layer 5 of each of the sub-pixels 21, 22, and 23 toward the second electrode 6 or the encapsulation layer 8. In addition, the reflective layer 41 is used to implement the micro cavity characteristic through reflection and re-reflection with the second electrode 6. To this end, the reflective layer 41 may include a reflective material for reflecting light. For example, the reflective material may be a metal, but is not necessarily limited thereto and may be any other material as long as it may reflect light.

Since the reflective layer 41 is disposed at a relatively lower position than the common emission layer 5 for emitting light, the light emitted from the common emission layer 5 may be reflected upward. Here, the upward indicates a direction in which the user can perceive light, for example, the side at which the encapsulation layer 8 or the color filter layer 9 is disposed. Therefore, it is possible to further increase the light efficiency of the first sub-pixel 21, the second sub-pixel 22, and the third sub-pixel 23 compared to a case in which there is no reflective layer 41, and the user can perceive high brightness, that is, clear image through the increased light efficiency. In other words, the user can perceive a clear image. The reflective layer 41 may be disposed inside the insulating layer 3.

The reflective layer 41 of each of the sub-pixels 21, 22, and 23 may be electrically connected to the transistors 31, 32, and 33 through the contact hole, and the connection electrode.

In one embodiment, the reflective layers 41 are positioned in the first sub-pixel 21, the second sub-pixel 22, and the third sub-pixel 23 at different heights with respect to the substrate 2. For example, the reflective layer 41 positioned in the first sub-pixel 21 may be positioned closest to the substrate 2, then the reflective layer 41 positioned in the third sub-pixel 23 may be positioned second closest to the substrate 2, and finally, the reflective layer 41 positioned in the second sub-pixel 22 may be positioned furthest from the substrate 2. Conversely, the reflective layer 41 positioned in the first sub-pixel 21 may be positioned farthest from the second electrode 6, then the reflective layer 41 positioned in the third sub-pixel 23 may be positioned the next farthest from the second electrode 6, and finally, the reflective layer 41 positioned in the second sub-pixel 22 may be positioned closest to the second electrode 6.

As described above, it is because when the reflective layer 41 is formed to have various separation distances (or resonance distances) from the second electrode 6, it is possible to increase the light extraction efficiencies of different colors through reflection and re-reflection between the reflective layer 41 and the second electrode 6 according to the separation distance. Therefore, it is possible to increase the light extraction efficiency of red light in the first sub-pixel 21, increase the light extraction efficiency of blue light in the second sub-pixel 22, and increase the light extraction efficiency of green light in the third sub-pixel 23.

The transparent layer 42 is disposed on the reflective layer 41. The transparent layer 42 is used to supply holes to the common emission layer 5. The transparent layer 42 may transparent so that the light reflected from the reflective layer 41 may travel upward. The transparent layer 42 may be made of a transparent material, but is not limited thereto and may be made of a thin metal material as long as it may transmit light. In addition, in the present specification, the first electrode 4 is described as having the double layer, but may have more layers. For example, the first electrode 4 may be formed by including a highly reflective metal material, such as a stacked structure (ITO/Al/ITO) of aluminum and ITO, an APC alloy, and a stacked structure (ITO/APC/ITO) of APC alloy and ITO. The APC alloy indicates an alloy of silver (Ag), palladium (Pb), and copper (Cu).

The transparent layer 42 may be electrically connected to the reflective layer 41 in direct contact with the reflective layer 41, or electrically connected to the reflective layer 41 by being indirectly connected to the reflective layer 41 through the contact hole and the connection electrode. The reflective layer 41 may be connected to each of the first to third transistors 31, 32, and 33 through another contact hole to transmit the driving voltage provided by each of the first to third transistors 31, 32, and 33 to the transparent layer 42. The transparent layer 42 may supply holes to the common emission layer 5 when the driving voltage is applied from the first to third transistors 31, 32, and 33.

The transparent layer 42 may be disposed for each of the first to third sub-pixels 21, 22, and 23 to have substantially the same height at the upper surface of the reflective layer 41 or the insulating layer 3. In addition, the reflective layer 41 may be provided to have the same width as the transparent layer 42, but is not necessarily limited thereto and may be provided to have a larger width than the transparent layer 42 to further increase the amount of light reflected upward.

Meanwhile, the insulating layer 3 according to one embodiment may include at least one indentation IDP. For example, the indentation IDP may be formed by being indented or recessed in the thickness direction from an upper surface of the insulating layer 3 toward a lower surface of the substrate 2. The indentation IDP may be located at the boundaries between the adjacent sub-pixels 21, 22, and 23. In one embodiment, the indentation IDP may indicate a space formed by an extension line extending horizontally from the upper surface of the insulating layer 3 in which no indentation IDP is formed and the inner surfaces and upper surface of the insulating layer 3 in which the indentation IDP is formed. A shape of the indentation IDP may be a rectangle or quadrangle, but is not limited thereto.

The bank BK may be disposed to cover an edge of the first electrode 4 or edges of the first electrode 4 and the reflective layer 41. The bank BK may be disposed at the boundaries of the adjacent sub-pixels 21, 22, and 23.

The bank BK is formed to surround and cover the edge of the transparent layer 42 on the insulating layer 3. Therefore, as shown in the cross-sectional view of FIG. 2, the bank BK may cover both ends of the transparent layer 42 provided in each of the first to third sub-pixels 21, 22, and 23. Specifically, the bank BK may be formed to cover a portion of upper surface and side surfaces at both ends of the transparent layer 42 and a portion of the upper surface of the insulating layer 3, and thus a current may be concentrated on the ends of the transparent layer 42, thereby solving the problem that luminous efficiency is reduced. The portion of the upper surface of the transparent layer 42 not covered and exposed by the bank BK becomes an emission area. The bank BK may be made of an organic insulating film or an inorganic insulating film. The bank BK may not overlap the indentation IDP in the thickness direction. The banks BK may not overlap each other at the boundaries of the adjacent sub-pixels 21, 22, and 23. In one embodiment, the bank BK is non-overlapping with the indentation IDP.

The common emission layer 5 is formed on the first electrode 4 and the insulating layer 3. The common emission layer 5 may be formed on the bank BK disposed between the plurality of sub-pixels 21, 22, and 23. Therefore, the common emission layer 5 may be in contact with the upper surface of the transparent layer 42 of the first electrode 4. The common emission layer 5 may be in contact with the upper surface of the transparent layer 42 exposed by the bank BK, the side surfaces and upper surfaces of the adjacent banks BK, and the upper surfaces of the insulating layers 3 adjacent to the indentation IDP.

The OLED according to one embodiment may include the first electrode 4 or ANO, the second electrode 6 or CAT, and the common emission layer 5 between the first electrode 4 and the second electrode 6.

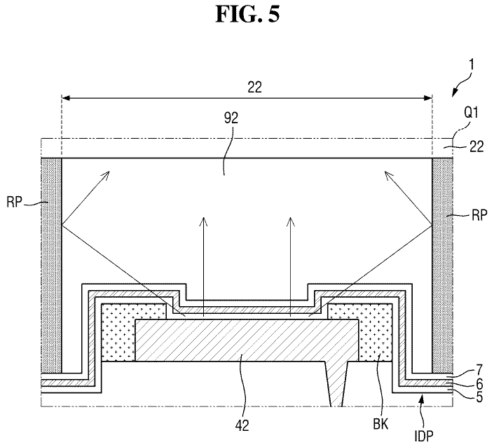

The common emission layer 5 may be provided to emit white (W) light. To this end, the common emission layer 5 may include a plurality of stacks for emitting light of different colors. Specifically, the common emission layer 5 may include a first stack, a second stack, and a charge generation layer CGL provided between the first stack and the second stack. Meanwhile, although FIG. 2 shows that the common emission layer 5 is formed integrally without physically separated at the indentation IDP (see FIG. 5), the common emission layer 5 may be separated physically at the indentation IDP. Therefore, it is possible to prevent a leakage current from any one of the sub-pixels 21, 22, and 23 to adjacent sub-pixels 21, 22, and 23. The feature that the common emission layer 5 is physically separated at the indentation IDP can be applied to all of embodiments below.

The second electrode 6 is formed on the common emission layer 5. The second electrode 6 may function as the cathode of the display device 2. Like the common emission layer 5, the second electrode 6 is formed in each of the sub-pixels 21, 22, and 23 and therebetween.

In the display device 1 according to one embodiment, the second electrode 6 may be formed as a translucent electrode to implement white light with luminous efficiency in the top emission type. Therefore, the micro cavity effect can be obtained for each of the first to third sub-pixels 21, 22, and 23. When the second electrode 6 is formed as the translucent electrode, reflection and re-reflection of light may be repeated between the second electrode 6 and the reflective layer 41 to obtain the micro cavity effect, thereby increasing light extraction efficiency.

Meanwhile, since the second electrode 6 is formed on the upper surface of the common emission layer 5, the second electrode 6 may be formed along a profile of the common emission layer 5. Since the common emission layer 5 is formed along a profile of the transparent layer 42 of the first electrode 4 in the emission area, as a result, the second electrode 6 may be formed along the profile of the transparent layer 42 of the first electrode 4. In addition, the capping layer 7 on the second electrode 6 may also be formed along a profile of the second electrode 6.

The capping layer 7 may be made of an inorganic insulating material, but is not limited thereto. The capping layer 7 may be disposed on the second electrode 6 to protect the OLED.

The color filter layer 9 is formed on the capping layer 7. The color filter layer 9 may include the red (R) first color filter 91 provided in the first sub-pixel 21, the blue (B) second color filter 92 provided in the second sub-pixel 22, and the green (G) third color filter 93 provided in the third sub-pixel 23, but is not necessarily limited thereto. The color filter layer 9 may include a reflective member RP disposed between the color filters 91, 92, and 93 and adjacent color filters 91, 92, and 93. The reflective member RP may be disposed at the boundaries of the adjacent sub-pixels 21, 22, and 23.

As shown in FIG. 3, the common emission layer 5 may include a first stack EL1, a second stack EL2, and a first charge generation layer CGL1, which are provided on the first electrode 4.

The first stack EL1 may be provided on the first electrode 4 and configured in a structure in which a hole injecting layer HIL, a hole transporting layer HTL, a blue (B) emitting layer EML1, and an electron transporting layer (ETL) may be stacked sequentially.

The first stack EL1 may be disposed between the first sub-pixel 21 and the second sub-pixel 22 and disposed between the second sub-pixel 22 and the third sub-pixel 23, that is, on the bank BK.

The first charge generation layer CGL1 functions to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metal material as a dopant.

The first charge generation layer CGL1 may be disposed between the first sub-pixel 21 and the second sub-pixel 22 and disposed between the second sub-pixel 22 and the third sub-pixel 23, that is, on the bank BK.

The second stack EL2 may be provided on the first stack EL1 and configured in a structure in which the hole transporting layer HTL, a yellow green (YG) emitting layer EML2, the electron transporting layer ETL, and the electron injecting layer EIL are stacked sequentially.

The second stack EL2 may be disposed between the first sub-pixel 21 and the second sub-pixel 22 and disposed between the second sub-pixel 22 and the third sub-pixel 23, that is, on the bank BK.

As a result, the common emission layer 5 may be provided as a common layer throughout the first to third sub-pixels 21, 22, and 23 as shown in FIG. 2.

As shown in FIG. 4, a common emission layer 5_1 of the OLED according to one embodiment may include the first stack EL1 provided on the first electrode 4, the second stack EL2, the third stack EL3, the first charge generation layer CGL1 between the first stack EL1 and the second stack EL2, and the second charge generation layer CGL2 between the second stack EL2 and the third stack EL3.

The first stack EL1 may be provided on the first electrode 4 and configured in a structure in which the hole injecting layer HIL, the hole transporting layer HTL, a blue (B) emitting layer EML1, and the electron transporting layer ETL are stacked sequentially.

The first stack EL1 may be disposed between the first sub-pixel 21 and the second sub-pixel 22 and disposed between the second sub-pixel 22 and the third sub-pixel 23, that is, on the bank BK.

The first charge generation layer CGL1 functions to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metal material as a dopant.

The first charge generation layer CGL1 may be disposed between the first sub-pixel 21 and the second sub-pixel 22 and disposed between the second sub-pixel 22 and the third sub-pixel 23, that is, on the bank BK.

The second stack EL2 may be provided on the first stack EL1 and configured in a structure in which the hole transporting layer HTL, a green (G) emitting layer EML2, the electron transporting layer ETL are stacked sequentially.

The second stack EL2 may be disposed between the first sub-pixel 21 and the second sub-pixel 22 and disposed between the second sub-pixel 22 and the third sub-pixel 23, that is, on the bank BK.

The second charge generation layer CGL2 functions to supply charges to the second stack EL2 and the third stack EL3. The second charge generation layer CGL2 may include an N-type charge generation layer for supplying electrons to the second stack EL2 and a P-type charge generation layer for supplying holes to the third stack EL3. The N-type charge generation layer may include a metal material as a dopant.

The second charge generation layer CGL2 may be disposed between the first sub-pixel 21 and the second sub-pixel 22 and disposed between the second sub-pixel 22 and the third sub-pixel 23, that is, on the bank BK.

The third stack EL3 may be provided on the second stack EL2 and configured in a structure in which the hole transporting layer HTL, a red (R) emitting layer EML3, the electron transporting layer ETL, and the electron injecting layer EIL are stacked sequentially.

Referring back to FIG. 2, the color filter layer 9 according to one embodiment may be disposed to fill the indentation IDP. That is, a portion of the color filter layer 9 is disposed within the indentation IDP. For example, the first color filter 91 may fill the indentation IDP in the first sub-pixel 21, the second color filter 92 may fill the indentation IDP in the second sub-pixel 22, and the third color filter 93 may fill the indentation IDP in the third sub-pixel 23. In other words, a portion of the first color filter 91 is disposed within the indentation IDP in the first sub-pixel 21, a portion of the second color filter 92 may be disposed within the indentation IDP in the second sub-pixel 22, and a portion of the third color filter 93 may be disposed within the indentation IDP in the third sub-pixel 23. In addition, a portion of the reflective member RP may fill the indentation IDP. More specifically, the reflective member RP may be disposed between the adjacent color filters 91, 92, and 93 and disposed in direct contact with the adjacent color filters 91, 92, and 93. Although a height of a surface of the reflective member RP may be the same as heights of surfaces of the adjacent color filters 91, 92, and 93, the present specification is not limited thereto. The reflective member RP may include reflective metal. The reflective member RP may include, for example, silver (Ag) or a silver (Ag) alloy, but is not limited thereto.

The first color filter 91, the reflective member RP, and the second color filter 92 may be sequentially disposed from the left in the indentations IDP of the first and second sub-pixels 21 and 22, and the second color filter 92, the reflective member RP, and the third color filter 93 may be sequentially disposed from the left in the indentations IDP of the second and third sub-pixels 22 and 23. Since the color filters 91, 92, 93 and the reflective member RP are disposed to fill the indentation IDP as described above, each of lower surfaces of the color filters 91, 92, 93 and the reflective member RP may be disposed under the lower surface of the transparent layer 42. Thus, a portion (e.g., lower surfaces) of each of the color filters 91, 92, 93 and a portion of the reflective member RP that is in the indentation IDP is closer to the substrate 2 than the lower surface of the transparent layer 42.

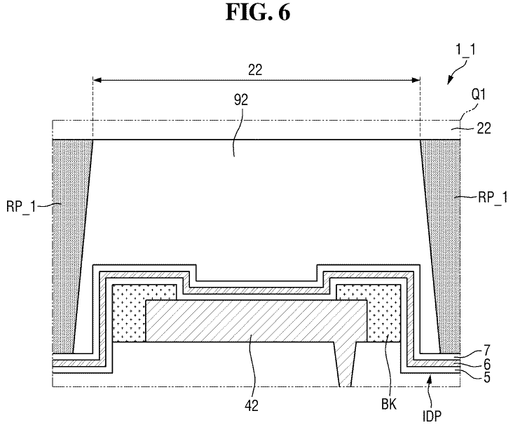

FIG. 5 is an enlarged view of area Q1 in FIG. 2 according to one embodiment. FIG. 6 is a modified example of the OLED of FIG. 5 according to one embodiment.

Referring to FIGS. 1 to 5, blue (B) light may be emitted from the common emission layer 5. Blue (B) light emitted from the common emission layer 5 may linearly travel upward, but as shown in FIG. 5, travel to the adjacent sub-pixels 21 and 23.

However, according to one embodiment, since the reflective member RP may be disposed at the boundaries of the sub-pixels 21, 22, and 23, and the reflective member RP may be disposed to fill the indentation IDP, the blue (B) light traveling to the adjacent sub-pixels 21 and 23 may be reflected by the reflective member RP to re-travel upward. Therefore, it is possible to improve light color mixing between the adjacent sub-pixels 21, 22, and 23. In addition, since the reflective member RP reflects the light emitted from each of the sub-pixels 21, 22, and 23, it is possible to minimize or at least reduce light loss. In addition, the color filters 91, 92, and 93 of the sub-pixels 21, 22, and 23 and the reflective members RP positioned at the boundaries of the adjacent sub-pixels 21, 22, and 23 are disposed to extend downward from the transparent layer 42, it is possible to compensate light color mixing and light loss which may occur under the transparent layer 42.

Meanwhile, the reflective member RP and the color filters 91, 92, and 93 shown in FIG. 5 may each have a rectangular cross-sectional shape.

However, as shown in FIG. 6, a cross-sectional shape of a reflective member RP_1 according to a modified example may be a reverse tapered shape where a width of an upper surface of the reflective member RP_1 is wider than a width of a lower surface of the reflective member RP_1. The cross-sectional shapes of the color filters 91, 92, and 93 in contact with the reflective member RP_1 may have a normal tapered shape.

However, the present specification is not limited thereto, and the cross-sectional shape of the reflective member RP_1 may be a normal tapered shape, and the cross-sectional shapes of the color filters 91, 92, and 93 in contact with the reflective member RP_1 may be a reverse tapered shape.

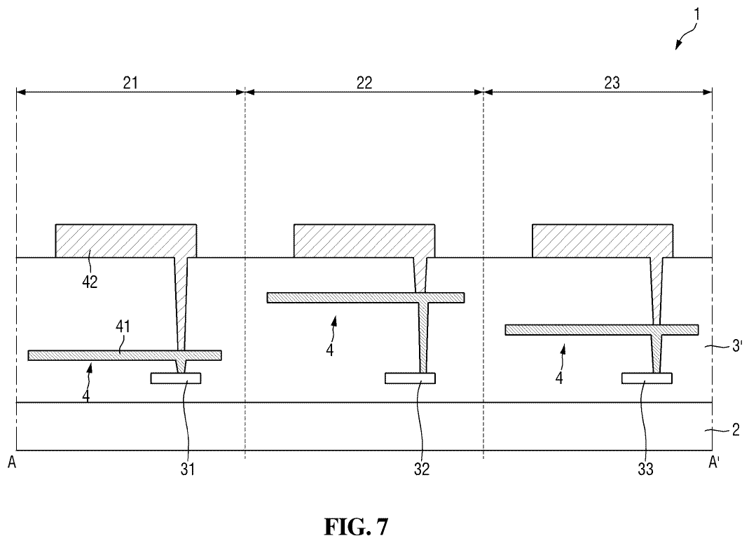

FIGS. 7 to 12 are cross-sectional views for each process showing a method of manufacturing the display device according to one embodiment. In describing the method of manufacturing the display device with reference to FIGS. 7 to 12, FIGS. 1 to 6 may be referred together.

Referring to FIGS. 2 and 7, the transparent layer 42 is formed on the insulating layer 3′ for each sub-pixel 21, 22, and 23. The transparent layer 42 is used to supply holes to the common emission layer 5. The transparent layer 42 may be provided transparently so that the light reflected from the reflective layer 41 may travel upward. The transparent layer 42 may be made of a transparent material, but is not limited thereto and may be made of a thin metal material as long as it may transmit light. In addition, in the present specification, the first electrode 4 is described as having the double layer, but may have more layers. For example, the first electrode 4 may be formed by including a highly reflective metal material, such as a stacked structure (ITO/Al/ITO) of aluminum and ITO, an APC alloy, and a stacked structure (ITO/APC/ITO) of APC alloy and ITO. The APC alloy indicates an alloy of silver (Ag), palladium (Pb), and copper (Cu).

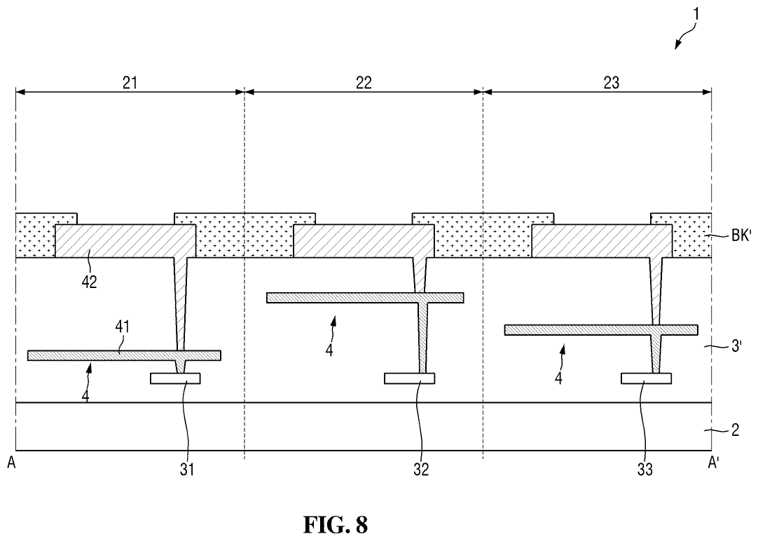

Subsequently, referring to FIGS. 2 and 8, a bank BK′ is formed at the boundaries of the adjacent sub-pixels 21, 22, and 23. The bank BK′ may be disposed between the transparent layers 42 disposed in each of the sub-pixels 21, 22, and 23. The bank BK′ is formed to surround and cover the edge of the transparent layer 42 on the insulating layer 3. Therefore, the bank BK′ may cover both ends of the transparent layer 42 provided in each of the first to third sub-pixels 21, 22, and 23. Specifically, the bank BK′ may be formed to cover a portion of upper surface and side surfaces at both ends of the transparent layer 42 and a portion of the upper surface of the insulating layer 3, and thus a current may be concentrated on the ends of the transparent layer 42, thereby solving the problem that luminous efficiency is reduced. The upper surface of the transparent layer 42 not covered and exposed by the bank BK′ becomes an emission area. The bank BK′ may be made of an organic insulating film or an inorganic insulating film.

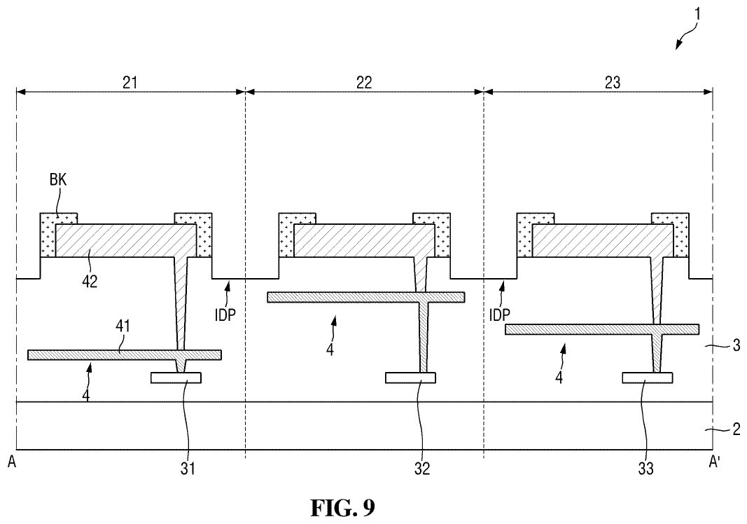

Subsequently, referring to FIGS. 2 and 9, the insulating layer 3′ and the bank BK′ of FIG. 8 are etched to form the insulating layer 3 in which the indentation IDP is formed, the indentation IDP, or the bank BK not disposed at the boundaries of the adjacent sub-pixels 21, 22, and 23.

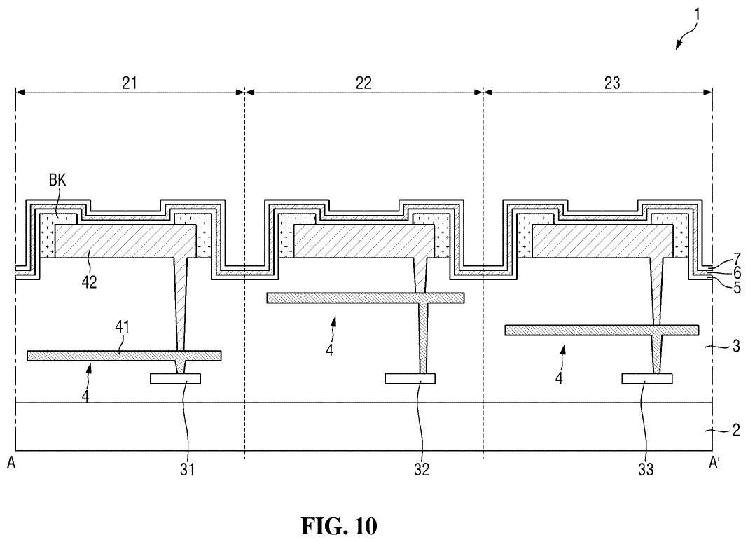

Subsequently, referring to FIGS. 2 and 10, the common emission layer 5 is formed on the transparent layer 42 and the bank BK, the second electrode 6 is formed on the common emission layer 5, and the capping layer 7 is formed on the second electrode 6. The common emission layer 5 may be formed on the bank BK disposed between the plurality of sub-pixels 21, 22, and 23. Therefore, the common emission layer 5 may be in contact with the upper surface of the transparent layer 42 of the first electrode 4. The common emission layer 5 may be in contact with the upper surface of the transparent layer 42 exposed by the bank BK, the side surfaces and upper surfaces of the adjacent banks BK, and the upper surfaces of the insulating layers 3 adjacent to the indentation IDP. The common emission layer 5 may be provided to emit white (W) light. To this end, the common emission layer 5 may include a plurality of stacks for emitting light of different colors. Specifically, the common emission layer 5 may include a first stack, a second stack, and a charge generation layer CGL provided between the first stack and the second stack. The second electrode 6 may function as the cathode of the display device 2. Like the common emission layer 5, the second electrode 6 is formed in each of the sub-pixels 21, 22, and 23 and therebetween. The capping layer 7 may be made of an inorganic insulating material, but is not limited thereto. The capping layer 7 may be disposed on the second electrode 6 to protect the OLED.

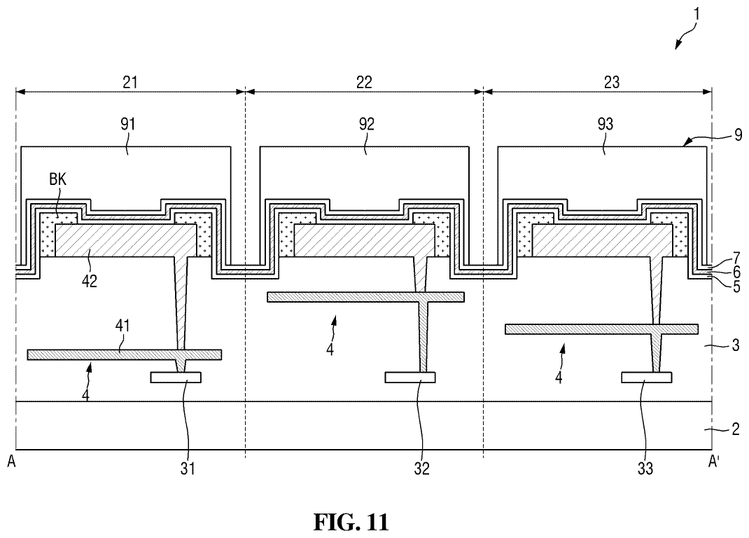

Subsequently, referring to FIGS. 2 and 11, the color filters 91, 92, and 93 are formed on the capping layer 7. The color filter layer 9 may include the red (R) first color filter 91 provided in the first sub-pixel 21, the blue (B) second color filter 92 provided in the second sub-pixel 22, and the green (G) third color filter 93 provided in the third sub-pixel 23, but is not necessarily limited thereto. Each of the color filters 91, 92, and 93 may additionally fill the indentation IDP. The first color filter 91 may fill the indentation IDP in the first sub-pixel 21, the second color filter 92 may fill the indentation IDP in the second sub-pixel 22, and the third color filter 93 may fill the indentation IDP in the third sub-pixel 23.

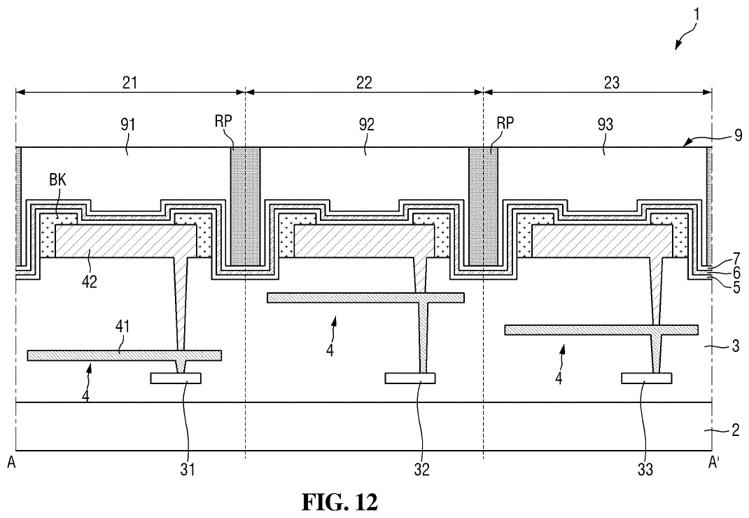

Subsequently, referring to FIGS. 2 and 12, the reflective member RP may be disposed between the adjacent color filters 91, 92, and 93 and disposed in direct contact with the adjacent color filters 91, 92, and 93. Although a height of a surface of the reflective member RP may be the same as heights of surfaces of the adjacent color filters 91, 92, and 93, the present specification is not limited thereto. The reflective member RP may include reflective metal. The reflective member RP may include, for example, silver (Ag) or a silver (Ag) alloy, but is not limited thereto.

The first color filter 91, the reflective member RP, and the second color filter 92 may be sequentially disposed from the left in the indentations IDP of the first and second sub-pixels 21 and 22, and the second color filter 92, the reflective member RP, and the third color filter 93 may be sequentially disposed from the left in the indentations IDP of the second and third sub-pixels 22 and 23. Since the color filters 91, 92, 93 and the reflective member RP are disposed to fill the indentation IDP as described above, each of lower surfaces of the color filters 91, 92, 93 and the reflective member RP may be disposed at a height that is lower than a height of the transparent layer 42 with respect to the substrate 2.

Hereinafter, other embodiments will be described. In describing the embodiments below, overlapping descriptions of the components already described in FIGS. 1 to 12 will be omitted.

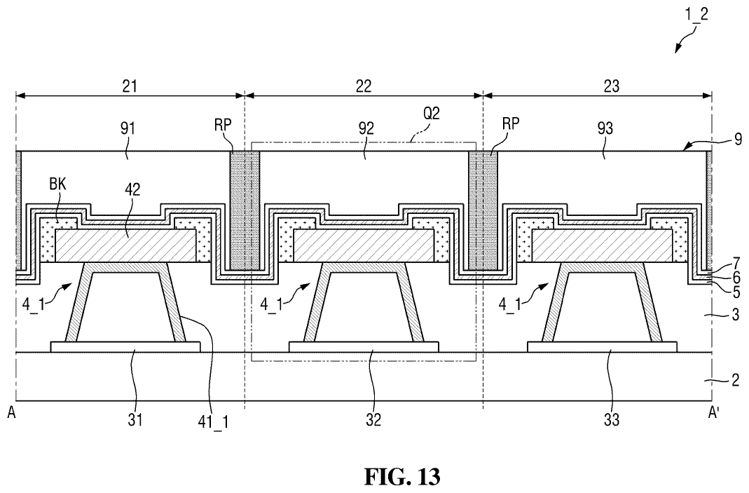

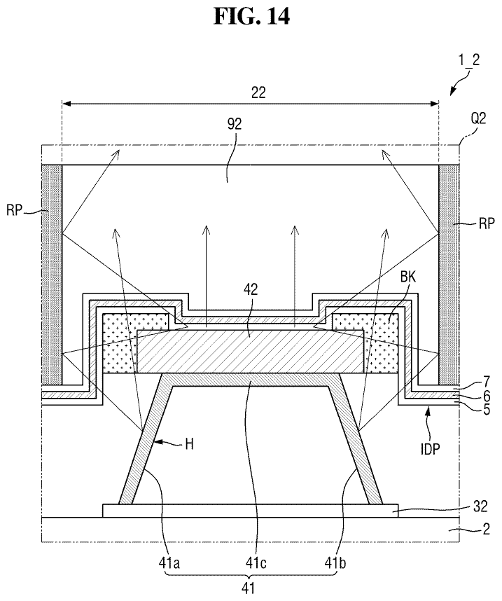

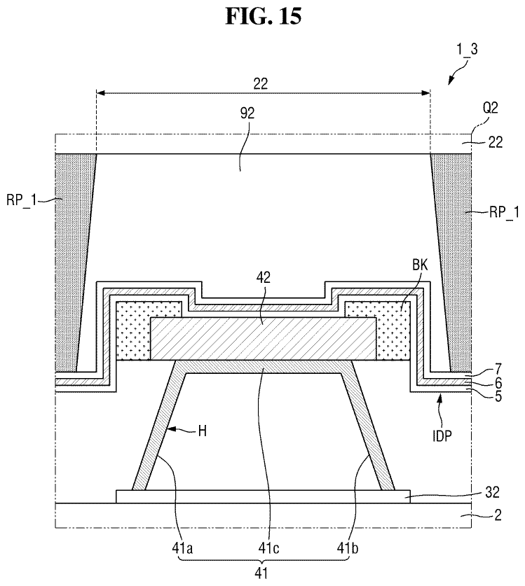

FIG. 13 is a cross-sectional view of a display device according to another embodiment. FIG. 14 is an enlarged view of area Q2 in FIG. 13 according to one embodiment. FIG. 15 is a modified example of the display device of FIG. 14 according to one embodiment.

Referring to FIGS. 13 to 15, a reflective layer 41_1 of a first electrode 4_1 of a display device 1_2 according to the present embodiment differs from the display device 1 shown in FIGS. 2 and 5 in that it may be inclined with respect to the extension direction of the substrate 2.

More specifically, the reflective layer 41_1 may be disposed in a hole H formed in the insulating layer 3. The reflective layer 41_1 may include portions inclined with respect to the extension direction of the substrate 2 and a portion connecting the corresponding portions.

For example, the reflective layer 41_1 may electrically connect each of the transistors 31, 32, and 33 with the transparent layer 42 in each of the sub-pixels 21, 22, and 23.

The reflective layer 41_1 may include a first part 41a (e.g., a first inclined part) in contact with the second transistor 32 and extending in an upper-right direction, a second part 41b (e.g., a second inclined part) in contact with the second transistor 32 and extending in an upper-left direction, and a third part 41c (e.g., a horizontal part) for connecting the first part 41a with the second part 41b. The first part 41a and the second part 41b may each be inclined with respect to the extension direction of the substrate 2. The first part 41a and the second part 41b may be disposed symmetrically in a left-right direction, but are not limited thereto. The first part 41a and the second part 41b may each be disposed in the hole H of the insulating layer 3. The hole H of the insulating layer 3 may provide a space where the first and second parts 41a and 41b are disposed. Although a lower surface of the third part 41c may be in contact with the upper surface of the insulating layer 3, and an upper surface of the third part 41c may be positioned colinearly with the upper surface of the insulating layer 3 on which no third part 41c is disposed, the present specification is not limited thereto. As described above, the reflective layer 41_1 according to the present embodiment may electrically connect each of the transistors 31, 32, and 33 with the transparent layer 42 in each of the sub-pixels 21, 22, and 23.

In addition, the reflective layer 41_1 may function to re-reflect the blue (B) light reflected from the reflective member RP to travel toward the substrate 2 upward. As described above, the first part 41a and the second part 41b may each be formed to be inclined with respect to the extension direction of the substrate 2 to easily reflect the blue (B) light reflected from the reflective member RP and traveling toward the substrate 2 upward.

Even in the present embodiment, as shown in FIG. 15, the reflective member RP of FIG. 14 may have a reverse tapered shape like the reflective member RP_1 of the display device 1_1 of FIG. 6. In some embodiments, the reflective member RP_1 may have a normal tapered shape. Since it has been described above in FIG. 6, detailed description thereof will be omitted.

Hereinafter, a method of manufacturing the display device according to another embodiment will be described.

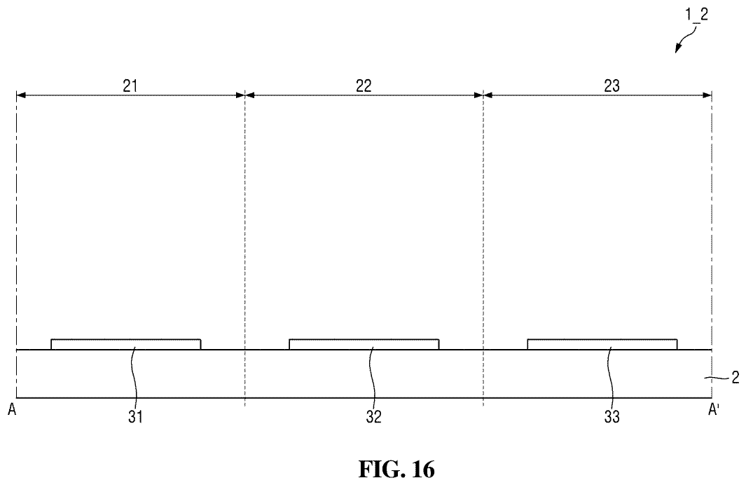

FIGS. 16 to 19 are cross-sectional views for each process showing a method of manufacturing the display device according to another embodiment. In describing the method of manufacturing the display device with reference to FIGS. 16 to 19, FIGS. 13 and 14 may be referred together.

Referring to FIGS. 13 and 16, the transistors 31, 32, and 33 are formed on the substrate 2.

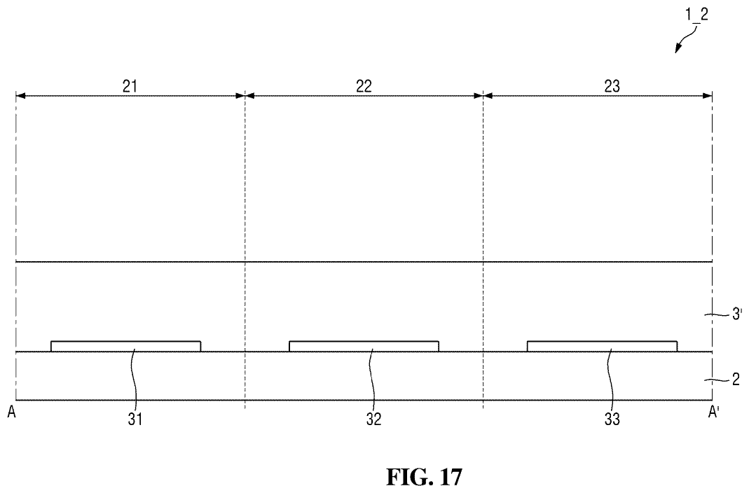

Subsequently, referring to FIGS. 13 and 17, the insulating layer 3′ is disposed on the transistors 31, 32, and 33. Although FIGS. 13 and 17 shows a case in which the insulating layer 3′ is disposed on the transistors 31, 32, and 33, the present specification is not limited thereto and the transistors 31, 32, and 33 may be formed in the insulating layer 3′.

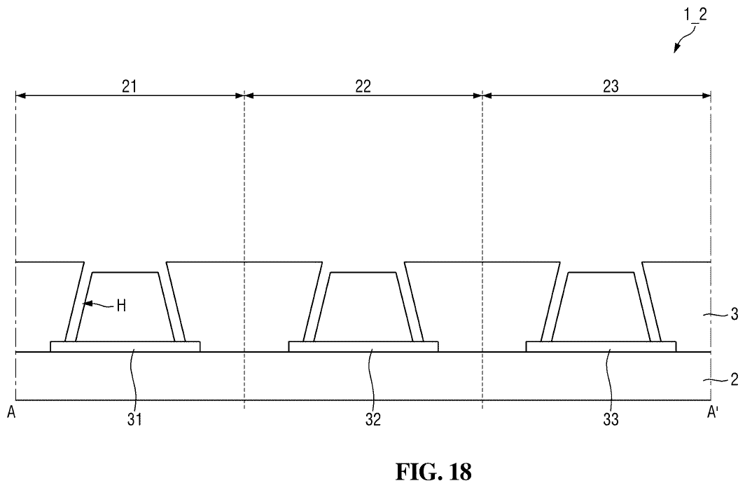

Subsequently, referring to FIGS. 13 and 18, the insulating layer 3 is formed. The insulating layer 3 may include two holes H for each sub-pixel 21, 22, and 23. The two holes H may be spaces where the first part 41a and the second part 41b described above in FIG. 14 are disposed. In addition, a height of a surface of the insulating layer 3 in an area where the third part 41c of FIG. 14 is disposed may be smaller than a height of a surface of the insulating layer 3 in an area where the third part 41c is not disposed.

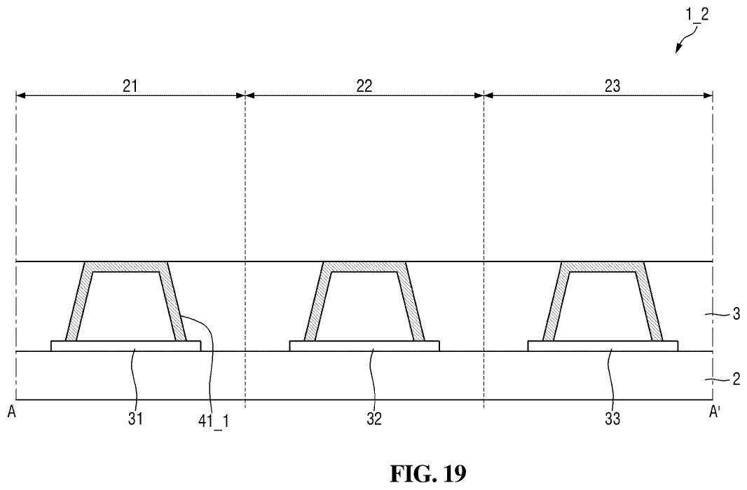

Subsequently, referring to FIGS. 13 and 19, the reflective layer 41_1 is formed on the holes H and the insulating layer 3. Since the reflective layer 41_1 has been described above in FIGS. 13 and 14, detailed description thereof will be omitted below.

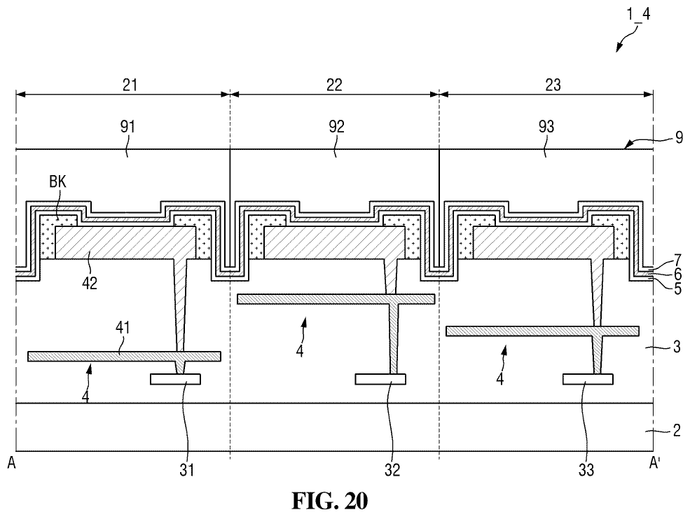

FIG. 20 is a cross-sectional view of a display device according to yet another embodiment.

Referring to FIG. 20, a display device 1_4 according to the present embodiment differs from the display device 1 shown FIG. 4 in that the reflective member RP shown FIG. 2 can be omitted.

More specifically, the color filters 91, 92, and 93 may be in contact with each other at the boundaries of the sub-pixels 21, 22, and 23.

Even in the present embodiment, the color filter layer 9 may be disposed to fill the indentation IDP. For example, the first color filter 91 may fill the indentation IDP in the first sub-pixel 21, the second color filter 92 may fill the indentation IDP in the second sub-pixel 22, and the third color filter 93 may fill the indentation IDP in the third sub-pixel 23.

Since the color filters 91, 92, 93 are disposed to fill the indentation IDP as described above, each of lower surfaces of the color filters 91, 92, 93 and the reflective member RP may be disposed at a height that is lower than a height of the lower surface of the transparent layer 42 with respect to the substrate 2.

According to the present embodiment, since the color filters 91, 92, and 93 are disposed to fill the indentation IDP, it is possible to minimize or at least reduce light mixing between the adjacent sub-pixels 21, 22, and 23 even under the transparent layer 42.

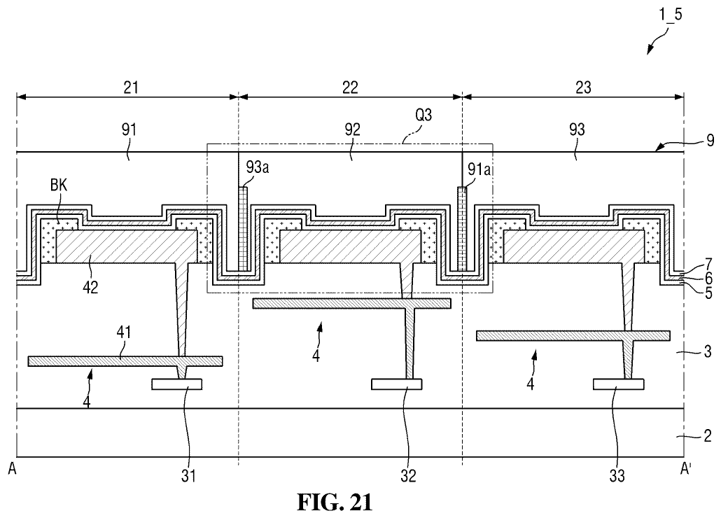

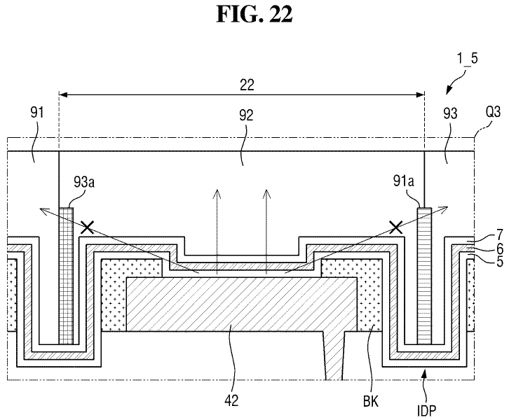

FIG. 21 is a cross-sectional view of a display device according to yet another embodiment. FIG. 22 is an enlarged view of area Q3 in FIG. 21 according to one embodiment.

Referring to FIGS. 21 and 22, the color filter layer 9 of the display device 1_5 according to the present embodiment differs from the display device 1_4 shown in FIG. 20 in that the color filters 91, 92, and 93 of the display device 1_5 according to the present embodiment may further include sub color filters 91a and 93a with colors which differ from those of the color filters 91, 92, and 93 adjacent to the boundaries between the adjacent sub-pixels 21, 22, and 23.

More specifically, the first sub color filter 91a may be disposed at a boundary between the second and third sub-pixels 22 and 23, and the second sub color filter 93a may be disposed at a boundary between the first and second sub-pixels 21 and 22. The first sub color filter 91a may be disposed under a portion of the adjacent second and third color filters 92 and 93. In other words, an upper surface of the first sub color filter 91a may be in contact with each of the second and third color filters 92 and 93, and side surfaces of the first sub color filter 91a may be in contact with the second and third color filters 92 and 93, respectively. The second sub color filter 93a may be disposed under the adjacent second color filter 92. In other words, an upper surface of the second sub color filter 93a may be in contact with the second color filter 92 and not with the first color filter 91. The side surfaces of the second sub color filter 93a may be in contact with the first and second color filters 91 and 92, respectively. Each of the sub color filter 91a and 93a may not have the same color as the adjacent color filters 91, 92 and 93. For example, the first sub color filter 91a may include the same material as the first color filter 91, and the second sub color filter 93a may include the same material as the third color filter 93. Each of the first and second sub color filters 91a and 93a may fill the indentation IDP, and lower surfaces of the first and second sub color filters 91a and 93a may each be in direct contact with the capping layer 7. Heights of surfaces of the sub color filters 91a and 93a may be smaller than heights of surfaces of the adjacent color filters 91, 92, and 93. The first color filter 91, the second sub color filter 93a, and the second color filter 92 may sequentially disposed near a boundary between the first and second sub-pixels 21 and 22, and the second color filter 92, the first sub color filter 91a, and the third color filter 93 may be sequentially disposed near a boundary between the second and third sub-pixels 22 and 23.

Since the first color filter 91, the second sub color filter 93a, and the second color filter 92 block different specific colors, as shown in FIG. 22, blue (B) light emitted to the side surface from the common emission layer 5 of the second sub-pixel 22 toward the second sub color filter 93a may not enter the first sub-pixel 21 by the second sub color filter 93a and the first color filter 91.

Likewise, since the second color filter 92, the first sub color filter 91a, and the third color filter 93 block different specific colors, as shown in FIG. 22, blue (B) light emitted to the side surface from the common emission layer 5 of the second sub-pixel 22 toward the first sub color filter 91a may not enter the third sub-pixel 23 by the first sub color filter 91a and the third color filter 93.

In other words, according to the display device 1_5 according to the present embodiment, three color filters 92, 93a, 91 or 92, 91a, and 93 may be sequentially disposed in a non-emission area or at the boundaries between the adjacent sub-pixels 21, 22, and 23, thereby preventing light color mixing between the adjacent sub-pixels 21, 22, and 23.

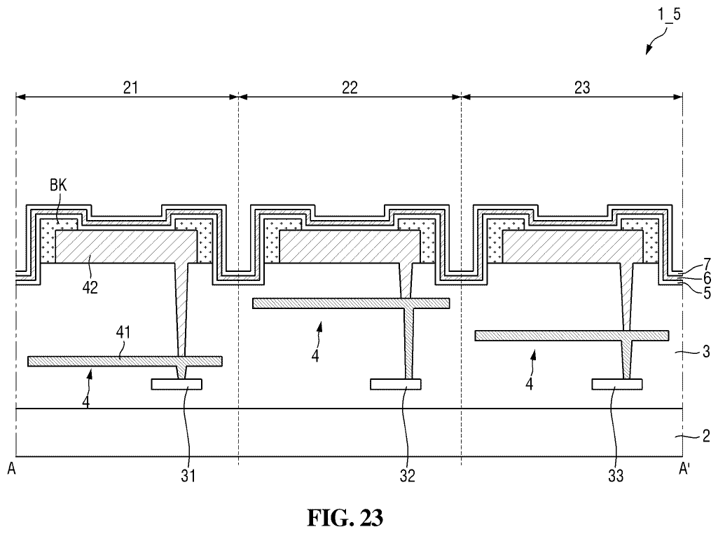

FIGS. 23 to 26 are cross-sectional views for each process showing a method of manufacturing the display device according to still another embodiment. In describing the method of manufacturing the display device with reference to FIGS. 23 to 26, FIGS. 21 and 22 may be referred together.

Referring to FIGS. 21 and 23, the capping layer 7 of FIG. 21 are also formed on the substrate 2.

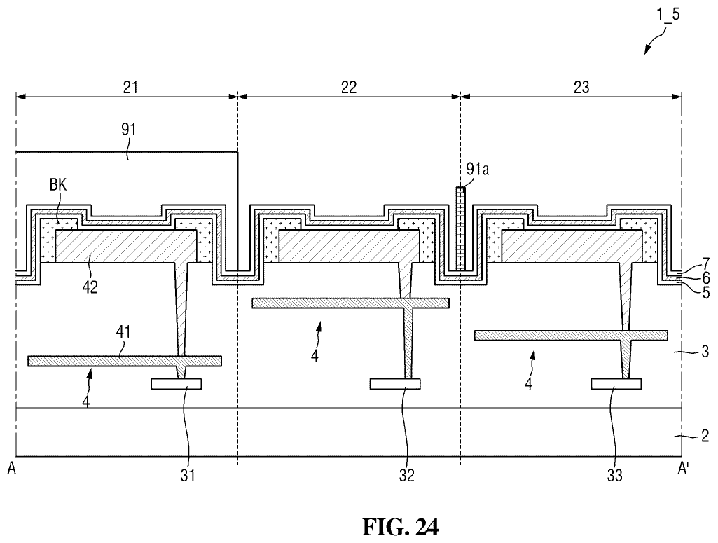

Subsequently, referring to FIGS. 21 and 24, the first color filter 91 is formed in the first sub-pixel 21 on the capping layer 7, and the first sub color filter 91a is formed at the boundary between the second and third sub-pixels 22 and 23. The first color filter 91 and the first sub color filter 91a may include the same material.

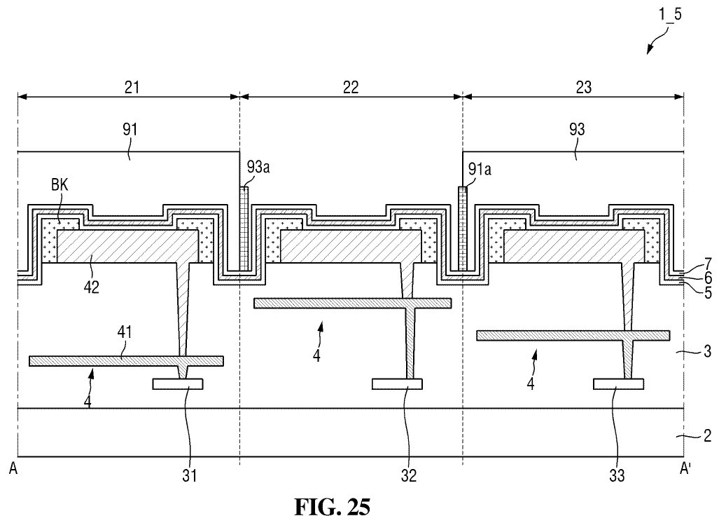

Subsequently, referring to FIGS. 21 and 25, the third color filter 93 is formed in the third sub-pixel 23 on the capping layer 7, and the second sub color filter 93a is formed at the boundary between the first and second sub-pixels 21 and 22. The third color filter 93 and the second sub color filter 93a may include the same material.

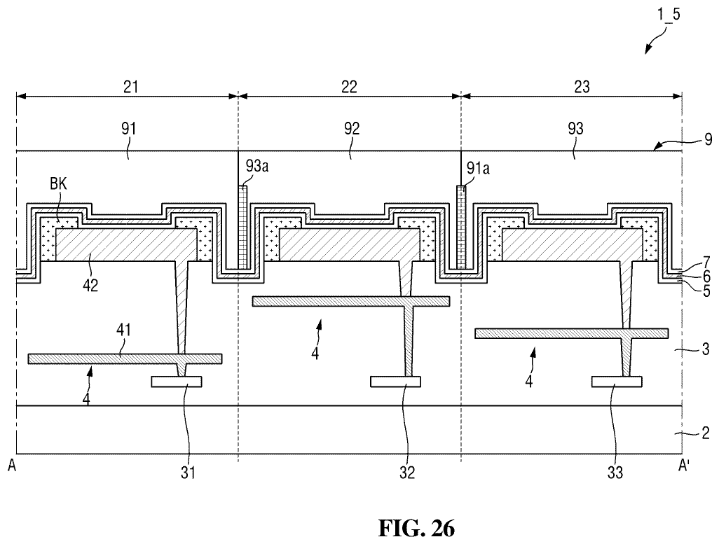

Subsequently, referring to FIGS. 21 and 26, the second color filter 92 is formed in the second sub-pixel 22 on the capping layer 7. The second color filter 92 may extend to the first sub-pixel 21, may be in direct contact with the first color filter 91, and connected to the upper surface of the second sub color filter 93a in the first sub-pixel 21. The second color filter 92 may be in direct contact with the third color filter 93 at the boundary between the second and third sub-pixels 22 and 23 and may be in direct contact with the upper surface of the first sub color filter 91a. The third color filter 93 may be in direct contact with the upper surface of the first sub color filter 91a at the boundary between the second and third sub-pixels 22 and 23.

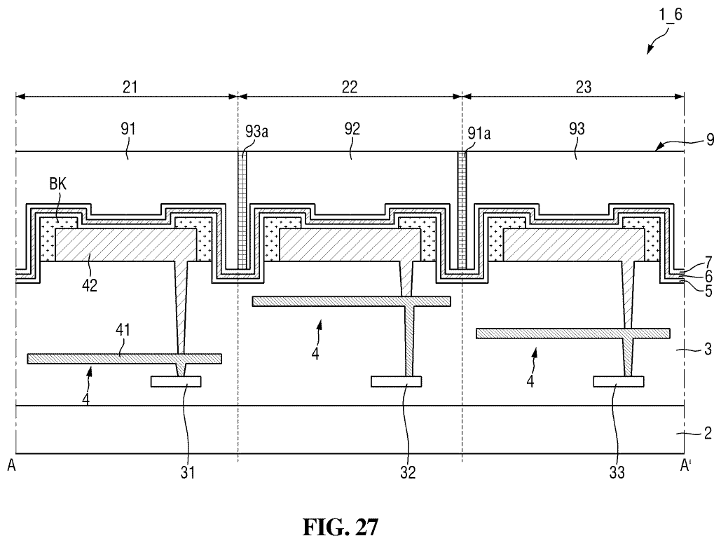

FIG. 27 is a cross-sectional view of a display device according to yet another embodiment.

Referring to FIG. 27, a display device 1_6 according to the present embodiment differs from the display device 1_5 shown in FIG. 21 in that the heights of the surfaces of the sub color filters 91a and 93a may be the same as the heights of the surfaces of the adjacent color filters 91, 92, and 93.

Since the remaining descriptions have been made above in FIGS. 21 and 22, detailed description thereof will be omitted below.

Although the embodiments have been described above with reference to the accompanying drawings, those skilled in the art to which the present specification pertains will be able to understand that the above-described technical configuration can be carried out in other specific forms without changing the technical spirit or essential features thereof. Therefore, it should be understood that the above-described embodiments are illustrative and not restrictive in all respects. In addition, the scope of the embodiments is indicated by the claims to be described below rather than the detailed description. In addition, the meaning and scope of the claims and all changed or modified forms derived from the equivalent concept thereof should be construed as being included in the scope of the embodiments.

### DESCRIPTION OF REFERENCE NUMERALS

1: display device
2: substrate
3: insulating layer
4: first electrode
5: common emission layer
6: second electrode
7: capping layer
8: encapsulation layer
9: color filter layer
BK: bank

What is claimed is:

1. A display device comprising:
a substrate having a pixel including a plurality of sub-pixels;
an insulating layer on the substrate, the insulating layer including an indentation that extends in a direction towards a lower surface of the substrate and the indentation located at boundaries between the plurality of sub-pixels;
an organic light emitting diode including a common emission layer on the insulating layer, the common emission layer in each of the plurality of sub-pixels; and
a color filter layer on the organic light emitting diode, the color filter layer including a plurality of color filters and a reflective member between adjacent color filters from the plurality of color filters.

2. The display device of claim 1, wherein a portion of each of the plurality of color filters is in the indentation.

3. The display device of claim 2, wherein a portion of the reflective member is in the indentation.

4. The display device of claim 3, wherein the organic light emitting diode includes a first electrode and the display device further comprises:
a bank between adjacent sub-pixels and on the first electrode of the organic light emitting diode.

5. The display device of claim 4, wherein the bank is non-overlapping with the indentation.

6. The display device of claim 1, wherein the reflective member has a reverse tapered shape.

7. The display device of claim 1, further comprising:
a capping layer between the plurality of color filters and the organic light emitting diode.

8. The display device of claim 7, wherein the organic light emitting diode includes a first electrode on the insulating layer, the common emission layer on the first electrode, and a second electrode on the common emission layer, and the plurality of color filters are in direct contact with the capping layer.

9. A display device comprising:
a substrate having a pixel including a plurality of sub-pixels;
an insulating layer on the substrate, the insulating layer including an indentation that extends in a direction towards a lower surface of the substrate and the indentation located at boundaries between the plurality of sub-pixels;
a plurality of transistors in the insulating layer, each of the plurality of transistors included in a corresponding one of the plurality of sub-pixels; and
a plurality of organic light emitting diodes that are each included in a corresponding one of the plurality of sub-pixels, each organic light emitting diode including a first electrode on the insulating layer and electrically connected to a corresponding transistor from the plurality of transistors, a common emission layer on the first electrode and is common to the plurality of organic light emitting diodes, and a second electrode on the common emission layer and is common to the plurality of organic light emitting diodes,
wherein the first electrode of at least one of the plurality of organic light emitting diodes includes a transparent layer on the insulating layer and a reflective layer that electrically connects the corresponding transistor with the transparent layer, and the reflective layer includes an inclined surface with respect to an extension direction of the substrate.

10. The display device of claim 9, wherein the reflective layer includes a first inclined part and a second inclined part that are inclined with respect to the extension direction of the substrate, and a third part that connects the first inclined part with the second inclined part and is connected to the transparent layer.

11. The display device of claim 10, further comprising:
a color filter layer on the second electrode, the color filter layer including a plurality of color filters and a reflective member between adjacent color filters from the plurality of color filters.

12. The display device of claim 11, wherein a portion of each of the plurality of color filters is in the indentation, and a portion of the reflective member is in the indentation.

13. The display device of claim 12, further comprising:
a bank between adjacent sub-pixels and on the first electrode of the organic light emitting diode, the bank non-overlapping with the indentation.

14. A display device comprising:
a substrate having a pixel including a plurality of sub-pixels;
an insulating layer on the substrate, the insulating layer including an indentation that extends in a direction towards a lower surface of the substrate and the indentation located at boundaries between the plurality of sub-pixels;
an organic light emitting diode including a common emission layer on the insulating layer, the common emission layer in each of the plurality of sub-pixels; and
a color filter layer on the organic light emitting diode, the color filter layer including a plurality of color filters and a portion of each of the plurality of color filters is in the indentation.

15. The display device of claim 14, wherein the plurality of sub-pixels include a first sub-pixel, a second sub-pixel, and a third sub-pixel,
wherein the plurality of color filters include a first color filter in the first sub-pixel, a second color filter in the second sub-pixel, and a third color filter in the third sub-pixel, and adjacent color filters from the plurality of color filters are in contact with each other at each of boundaries between the plurality of sub-pixels.

16. The display device of claim 15, wherein the plurality of color filters further comprise:
a first sub color filter at a boundary between the first sub-pixel and the second sub-pixel, the first sub color filter including a same material as the third color filter.

17. The display device of claim 16, wherein the first sub color filter is in contact with each of the first color filter and the second color filter.

18. The display device of claim 17, wherein the plurality of color filters further comprises:
a second sub color filter at a boundary between the second sub-pixel and the third sub-pixel, the second sub color filter including a same material as the first color filter.

19. The display device of claim 18, wherein the second sub color filter is in contact with each of the second color filter and the third color filter.

20. A display device comprising:
a substrate including a plurality of sub-pixels;
an insulating layer on the substrate;
a plurality of light emitting diodes, each of the plurality of light emitting diodes included in a corresponding one of the plurality of sub-pixels and comprises a first electrode on an upper surface of the insulating layer, an emission layer on the first electrode and included in the plurality of sub-pixels, and a second electrode on the first electrode and included in the plurality of sub-pixels; and
a plurality of color filters over the plurality of light emitting diodes,
wherein a portion of a color filter from the plurality of color filters that is located at a boundary between adjacent sub-pixels from the plurality of sub-pixels is closer to the substrate than a lower surface of the first electrode.

21. The display device of claim 20, wherein the insulating layer includes an indentation that extends in a direction towards a lower surface of the substrate and the indentation is located at the boundary between the adjacent sub-pixels.

22. The display device of claim 21, wherein the portion of the color filter is in the indentation.

23. The display device of claim 22, wherein a portion of the emission layer and a portion of the second electrode is in the indentation.

24. The display device of claim 22, further comprising:
a reflective member at the boundary between the adjacent sub-pixels, the reflective member including a portion that is in the indentation.

25. The display device of claim 22, further comprising:
a bank between the adjacent sub-pixels and on the first electrode of each of plurality of light emitting diodes, the bank non-overlapping with the indentation.
